(19) United States
(12) Patent Application Publication
(10) Pub. No.: US 2025/0098469 A1
(43) Pub. Date: Mar. 20, 2025

(54) LIGHT EMITTING DISPLAY DEVICE

(71) Applicant: LG Display Co., Ltd., Seoul (KR)

(72) Inventors: Pu-Reum KIM, Paju-si (KR); Chang-Hwa JUN, Paju-si (KR)

(73) Assignee: LG Display Co., Ltd., Seoul (KR)

(21) Appl. No.: 18/882,233

(22) Filed: Sep. 11, 2024

(30) Foreign Application Priority Data
Sep. 18, 2023 (KR) 10-2023-0123910

(51) Int. Cl. H10K 59/35; H10K 59/122; H10K 59/123; H10K 59/124; H10K 59/38; H10K 59/80; H10K 59/88

(52) U.S. Cl. CPC H10K 59/353; H10K 59/122; H10K 59/123; H10K 59/124; H10K 59/38; H10K 59/879; H10K 59/8792; H10K 59/88

(57) ABSTRACT

A light emitting display device in one example can include a display region having a first display region with subpixels in a stripe manner and a second display region with the subpixels in a delta manner, a first electrode in each of first and second subpixels in the first and second display regions, a bank including a first trench along a boundary of each column line of the display region, a light emitting layer on the first electrode and the bank, a second electrode on the light emitting layer, and a color filter pattern corresponding to each of the first and second subpixels. In the second display region, a dummy subpixel is arranged alternately with the second subpixel along column and row lines. The first and second subpixels in a first column line crossing the first and second display regions display the first color.

### CROSS-REFERENCE TO RELATED APPLICATIONS

The present application claims priority to Korean Patent Application No. 10-2023-0123910 filed in Republic of Korea on Sep. 18, 2023, the entire contents of which is hereby expressly incorporated by reference into the present application.

### BACKGROUND

### Field of the Invention

The present invention relates to a light emitting display device.

### Discussion of the Related Art

Recently, flat panel display devices having excellent characteristics such as thinness, light weight, and low power consumption have been widely developed and applied to various fields.

Among the flat panel display devices, a light emitting display device uses a light emitting element in which charges are injected into a light emitting layer formed between an anode and a cathode to form pairs of electrons and holes. Then, the pairs of electronics and holes disappear to emit light.

Recently, a light emitting display device is used as a display device for electronic devices that implement virtual reality (VR), augmented reality (AR), or mixed reality (MR).

However, the light emitting display device can have a limitation with a non-uniform color viewing angle as it uses subpixels arranged in a stripe manner.

### SUMMARY OF THE INVENTION

An advantage of the present invention is to provide a light emitting display device that can improve a color viewing angle.

Another object of the present invention is to provide a light emitting display device that can address the above-identified limitations and other issues associated with the related art.

Additional features and advantages of the invention will be set forth in the description which follows, and in part will be apparent from the description, or can be learned by practice of the invention. These and other advantages of the invention will be realized and attained by the structure particularly pointed out in the written description and claims hereof as well as the appended drawings.

To achieve these and other advantages and in accordance with the purpose of the present invention, as embodied and broadly described herein, a light emitting display device includes a substrate on which a display region is defined, the display region including a first display region in which subpixels of first to third colors are arranged in a stripe manner, and a second display region which is located outside the first display region and in which the subpixels of the first to third colors are arranged in a delta manner; a first electrode formed in each of first subpixels disposed in the first display region and each of second subpixels disposed in the second display region; a bank including a first trench formed along a boundary of each column line of the display region and covering an edge of the first electrode; a light emitting layer formed on the first electrode and the bank; a second electrode formed on the light emitting layer; and a color filter pattern located on the second electrode and corresponding to each of the first and second subpixels, wherein in the second display region, a dummy subpixel is arranged alternately with the second subpixel along column lines and row lines and has a size corresponding to the second subpixel, and wherein the first and second subpixels arranged in a first column line crossing the first and second display regions display the first color.

In another aspect of the present invention, a light emitting display device includes a substrate on which a display region is defined, the display region including a first display region in which subpixels of first to third colors are arranged in a stripe manner, and a second display region which is located outside the first display region and in which the subpixels of the first to third colors are arranged in a delta manner; a light emitting diode provided in the subpixel and including first and second electrodes and a light emitting layer disposed between the first and second electrodes; a first trench formed along a boundary of each column line of the display region and separating adjacent light emitting layers; and a color filter pattern corresponding to the subpixel and located on the light emitting diode, wherein in the second display region, a dummy subpixel is arranged alternately with the subpixel along column lines and row lines, and wherein in a first column line crossing the first and second display regions, first subpixels arranged in the first display region and second subpixels arranged in the second display region display the first color.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIGS. 1 and 2 are plan views schematically illustrating an arrangement of subpixels and an arrangement of color filter patterns of a light emitting display device according to a first embodiment of the present invention, respectively;

FIGS. 3 and 4 are views enlarging regions A of FIGS. 1 and 2, respectively;

FIG. 5 is a cross-sectional view taken along a line V-V′ of FIG. 3;

FIG. 6 is a cross-sectional view taken along a line VI-VI′ of FIG. 3;

FIG. 7 is a cross-sectional view taken along a line VII-VII′ of FIG. 3;

FIGS. 8 and 9 are plan views schematically illustrating an arrangement of subpixels and an arrangement of color filter patterns of a light emitting display device according to a second embodiment of the present invention, respectively;

FIG. 10 is a view enlarging a region B of FIG. 9;

FIG. 11 is a cross-sectional view schematically illustrating a cross-sectional structure of subpixels arranged along a horizontal direction in a first display region of a light emitting display device according to the second embodiment of the present invention;

FIG. 12 is a cross-sectional view schematically illustrating a cross-sectional structure of subpixels arranged along a horizontal direction in a second display region of a light-emitting display device according to the second embodiment of the present invention;

FIG. 13 is a plan view schematically illustrating an arrangement of subpixels of a light emitting display device according to a third embodiment of the present invention;

FIG. 14 is a plan view schematically illustrating an arrangement of color filter patterns and black matrices of a light emitting display device according to the third embodiment of the present invention;

FIG. 15 is a view enlarging a region C of FIG. 14;

FIG. 16 is a cross-sectional view schematically illustrating a cross-sectional structure of subpixels arranged along a horizontal direction in a second display region of a light emitting display device according to the third embodiment of the present invention;

FIGS. 17 and 18 are plan views schematically illustrating an arrangement of subpixels and an arrangement of color filter patterns of a light emitting display device according to a fourth embodiment of the present invention, respectively;

FIGS. 19 and 20 are views enlarging regions D of FIGS. 17 and 18, respectively;

FIG. 21 is a cross-sectional view taken along a line XXI-XXI′ of FIG. 19;

FIGS. 22 and 23 are plan views schematically illustrating an arrangement of subpixels and an arrangement of color filter patterns of a light emitting display device according to a fifth embodiment of the present invention, respectively;

FIG. 24 is a view enlarging a region E of FIG. 22;

FIG. 25 is a plan view schematically illustrating an arrangement of subpixels of a light emitting display device according to a sixth embodiment of the present invention;

FIG. 26 is a plan view schematically illustrating an arrangement of color filter patterns and black matrices of a light emitting display device according to the sixth embodiment of the present invention; and

FIG. 27 is a view enlarging a region F of FIG. 25.

### DETAILED DESCRIPTION OF THE EMBODIMENTS

Advantages and features of the present invention and methods of achieving them will be apparent with reference to the embodiments described below in detail with the accompanying drawings. However, the present invention is not limited to the embodiments disclosed below, but can be realized in a variety of different forms, and only these embodiments allow the present invention to be complete. The present invention is provided to fully inform the scope of the invention to the skilled in the art of the present disclosure, and the present invention can be defined by the scope of the claims.

The shapes, sizes, proportions, angles, numbers, and the like disclosed in the drawings for explaining the embodiments of the present invention are illustrative, and the present invention is not limited to the illustrated matters. The same reference numerals refer to the same components throughout the description.

Furthermore, in describing the present invention, if it is determined that a detailed description of the related known technology unnecessarily obscure the subject matter of the present invention, the detailed description thereof can be omitted. When ‘comprising’, ‘including’, ‘having’, ‘consisting’, and the like are used in this invention, other parts can be added unless ‘only’ is used. When a component is expressed in the singular, cases including the plural are included unless specific statement is described.

In interpreting the components, even if there is no separate explicit description, it is interpreted as including a margin range.

In the case of a description of a positional relationship, for example, when the positional relationship of two parts is described as ‘on’, ‘over’, ‘above’, ‘below’, ‘beside’, ‘under’, and the like, one or more other parts can be positioned between such two parts unless ‘right’ or ‘directly’ is used.

In the case of a description of a temporal relationship, for example, when a temporal precedence is described as ‘after’, ‘following’, ‘before’, and the like, cases that are not continuous can be included unless ‘directly’ or ‘immediately’ is used.

In describing components of the present invention, terms such as first, second and the like can be used. These terms are only for distinguishing the components from other components, and an essence, order, order, or number of the components is not limited by the terms.

Respective features of various embodiments of the present invention can be partially or wholly connected to or combined with each other and can be technically interlocked and driven variously, and respective embodiments can be independently implemented from each other or can be implemented together with a related relationship. Further, the term “can” fully encompasses all the meanings and coverages of the term “may.”

Hereinafter, various embodiments of the present invention are described in detail with reference to the drawings. All the components of each display device according to all embodiments of the present invention are operatively coupled and configured. Meanwhile, in the following embodiments, the same and like reference numerals are assigned to the same and like components, and detailed descriptions thereof can be omitted.

### First Embodiment

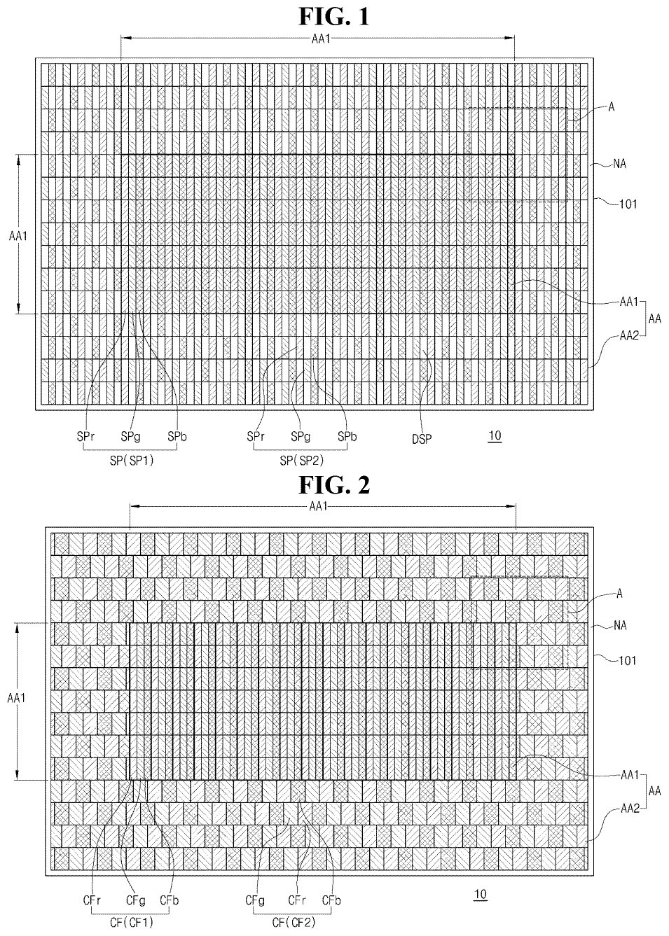

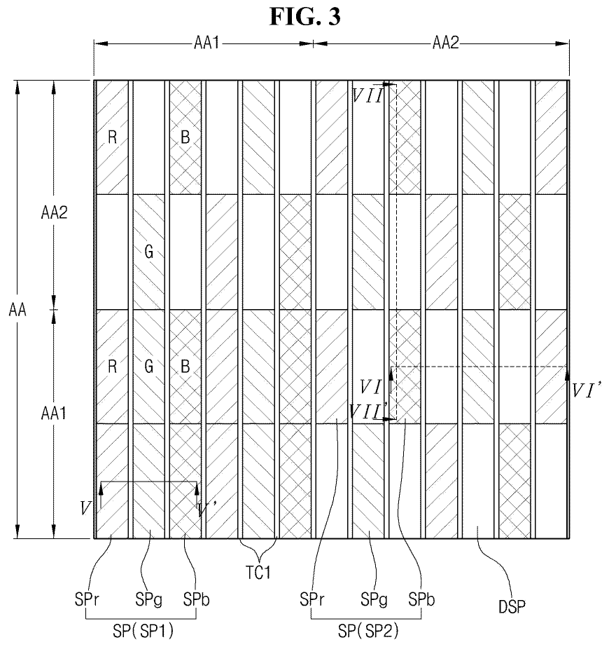

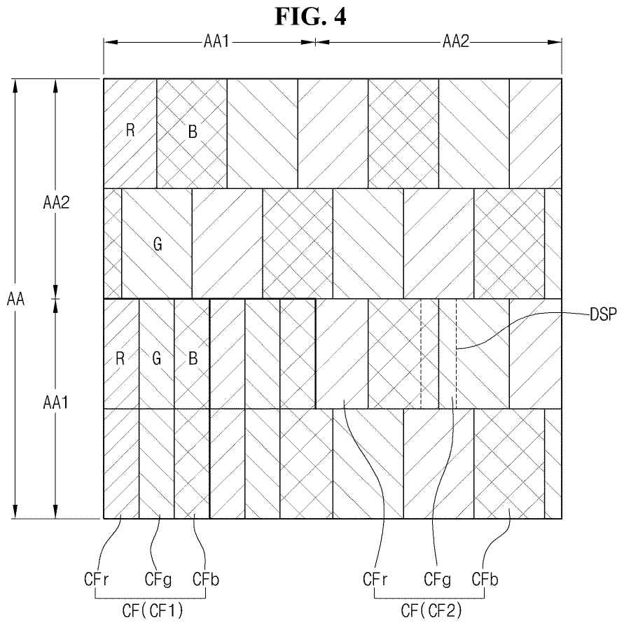

FIGS. 1 and 2 are plan views schematically illustrating an arrangement of subpixels and an arrangement of color filter patterns of a light emitting display device according to a first embodiment of the present invention, respectively. FIGS. 3 and 4 are views enlarging regions A of FIGS. 1 and 2, respectively.

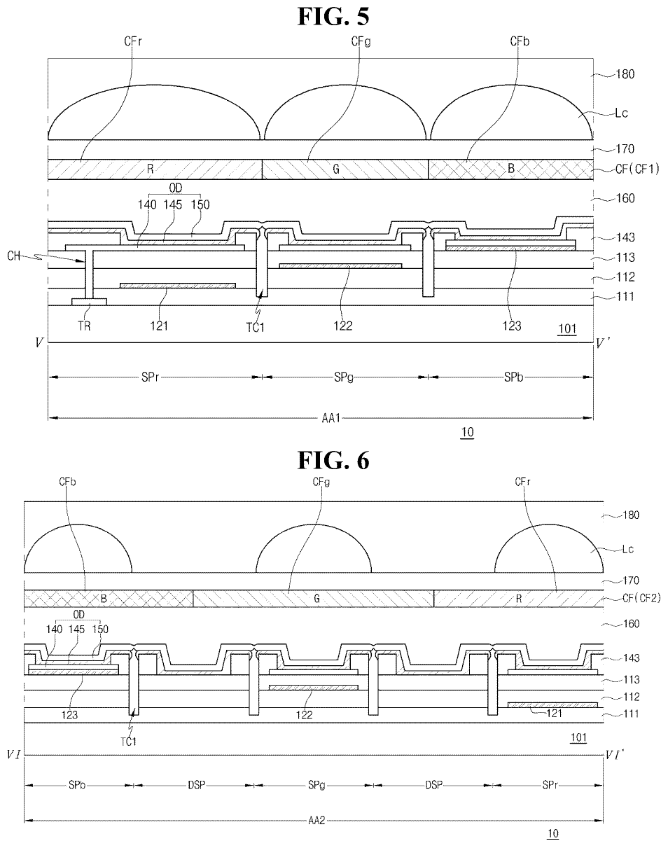

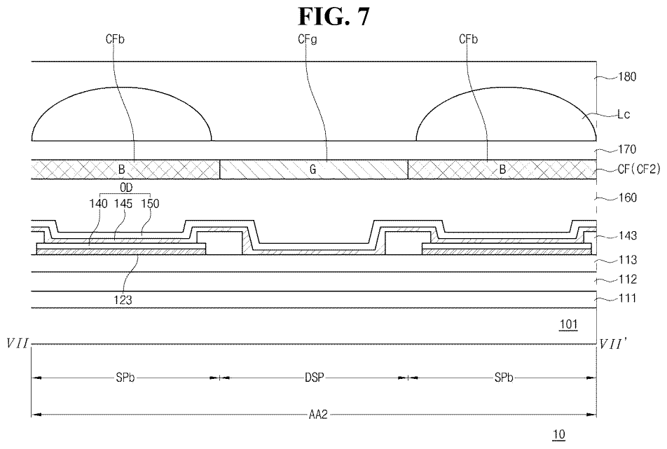

FIG. 5 is a cross-sectional view taken along a line V-V′ of FIG. 3. FIG. 6 is a cross-sectional view taken along a line VI-VI′ of FIG. 3. FIG. 7 is a cross-sectional view taken along a line VII-VII′ of FIG. 3.

Prior to a detailed description, a light emitting display device 10 according to an embodiment of the present invention can be any one of all types of display devices that display images with a light emitting diode OD which is a self-luminescent emitting element.

In this embodiment, for convenience of explanation, an organic light emitting display device is used as the light emitting display device 10 as an example.

In addition, the light emitting display device 10 can be a display device used in a VR, AR, or MR-based electronic device that displays a virtual image or a mixture of a virtual image and an external real image, but not limited thereto.

In addition, the light emitting display device 10 can be a top emission type display device or bottom emission type display device, or a dual emission type display device. In this embodiment, for convenience of explanation, the top emission type light emitting display device 10 is taken as an example.

Referring to FIGS. 1 to 7, the light emitting display device 10 of this embodiment can include a display region (or active region) AA that displays an image, and a non-display region (or non-active region) NA located outside the display region AA and surrounding the display region AA. The non-display region NA can surround the display region AA entirely or only in part(s).

In the display region AA, a plurality of subpixels SP for displaying an image can be arranged along a plurality of row lines (or horizontal lines) and column lines (or vertical lines) on a substrate 101. Meanwhile, a plurality of gate lines extending along a horizontal direction (or first direction) that is the row direction, and a plurality of data lines extending along a vertical direction (or second direction) that is the column direction can be formed on the substrate 101. Each subpixel SP can be connected to corresponding gate line and data line.

Here, the plurality of subpixels SP can include subpixels that constitute a unit pixel for displaying a color image and respectively display first, second, and third colors as different colors that implement white. For example, the plurality of subpixels SP can include red (R), green (G), and blue (B) subpixels SPr, SPg, and SPb that respectively displays red (R), green (G), and blue (B). Embodiments are not limited thereto. As an example, the plurality of subpixels SP can include subpixels respectively display three or more colors as different colors that implement white or a color other than while. As an example, a white subpixel displays white can be further included. As an example, subpixels displaying other colors such as cyan, magenta, or yellow, etc., can be additionally or alternatively included.

Each subpixel (SP) can include the light emitting diode (OD) which is a light emitting element. In addition, the subpixel SP can include a plurality of thin film transistors TR and at least one capacitor as a driving circuit for driving the light emitting diode OD.

Meanwhile, in this embodiment, the display region AA can include a first display region AA1 and a second display region AA2 having different resolutions.

In this regard, for example, the first display region AA1 is a region defined in a center portion of the display region AA and can have a first resolution that is relatively high. The second display region AA2 is a region defined in an outer portion of the display region AA and can have a second resolution that is relatively low. In other words, the second display region AA2, which has the second resolution lower than the first resolution, can be defined as being located along a periphery of the first display region AA1 and surrounding the first display region AA1.

As such, in this embodiment, the high-resolution first display region AA1 can be placed in the center portion of the display region AA, and the low-resolution second display region AA2 can be placed on the outer portion of the display region AA. As an example, the center portion can occupy half or more than half area of the display region AA, without being limited thereto. As an example, the boundary between the first display region AA1 and the second display region AA2 can be closer to the center of the display region AA than to the circumference of the display region AA, or can be closer to the circumference of the display region AA than to the center of the display region AA, without being limited thereto. As an example, the boundary between the first display region AA1 and the second display region AA2 can have a circular shape, a rounded shape or a rectangular shape, without being limited thereto.

In this case, a user can view a more natural image. In this regard, when the light emitting display device 10 is used as a display device for an electronic device such as VR, AR, or MR type device, the first display region AA1 can be located in the user's main visual field and can be set in a focus region of the electronic device. Accordingly, when the user watches a high-resolution image portion displayed in the first display region AA1 in the main visual field, a low-resolution image portion displayed in the second display region AA2 can be viewed in a peripheral visual field outside the main visual field. Accordingly, the user can view a natural image, thereby improving sense of immersion in the image.

In the high-resolution first display region AA1, for example, the subpixels SP can be arranged in a stripe manner. In this regard, the subpixels SP of the same color can be continuously arranged along each column line, and the subpixels SP of different colors constituting a unit pixel can be arranged alternately along the row direction.

In this regard, referring to FIGS. 1 and 3, for example, the red (R), green (G), and blue (B) subpixels SPr, SPg, and SPb can be alternately and repeatedly arranged along each row line. In addition, the red (R) subpixels SPr can be continuously arranged along the corresponding column line (e.g., a first column line), and the green (G) subpixels SPg can be continuously arranged along the corresponding column line (e.g., a second column line), and the blue (B) subpixels SPb can be continuously arranged along the corresponding column line (e.g., a third column line).

As such, in the first display region AA1, the subpixels (SP) of the same color can be continuously arranged in each column line, and the subpixels SPr, SPg, and SPb of different colors can be alternately and repeatedly arranged along the horizontal direction. In this case, the red (R), green (G), and blue (B) subpixels SPr, SPg, and SPb adjacent to each other in each row line can constitute a unit pixel.

Meanwhile, for convenience of explanation, the subpixels SP disposed in the first display region AA1 can be referred to as first subpixels SP1.

In the low-resolution second display region AA2, for example, the subpixels SP can be arranged in a delta manner. In this regard, the subpixels SP of different colors constituting a unit pixel can be arranged in a delta shape on a plane. For instance, these subpixels SP of a pixel can form a delta (e.g., triangle) shape.

In this regard, referring to FIGS. 1 and 3, for example, red (R), green (G), and blue (B) subpixels SPr, SPg, and SPb can be alternately and repeatedly arranged along each row line with and be spaced apart by one column line (or a width of a column line), and the subpixels SP of the same color can be arranged along each column line and be spaced apart by one row line (or a length of a row line). In two neighboring row lines, the red (R), green (G), and blue (B) subpixels SPr, SPg, and SPb can be alternately arranged in a zigzag shape along the horizontal direction.

As such, in the second display region AA2, the neighboring subpixels SP in each row line and each column line can be spaced apart from each other by substantially a size of the subpixel SP. The spaced region between the neighboring subpixels SP substantially corresponds to a non-emission region, and can be referred to as a non-emissive dummy subpixel DSP.

Since no light emitting diode OD is substantially formed in such the non-emissive dummy subpixel DSP, the non-emissive dummy subpixel DSP may not have an emission function.

In each column line of the second display region AA2, the dummy subpixel DSP can be located between two neighboring subpixels SP of the same color, so that the subpixel SP and the dummy subpixel DSP can be arranged alternately.

In addition, in each row line of the second display region AA2, the dummy subpixel DSP can be located between two neighboring subpixels SP of different colors, so that the subpixel SP and the dummy subpixel DSP can be arranged alternately.

According to the planar arrangement of the subpixels SP in the second display region AA2 as described above, a delta arrangement can be implemented in the second display region AA2. In this regard, each pixel can be configured with the red (R), green (G), and blue (B) subpixels SPr, SPg, and SPb arranged in a delta shape, and the non-emissive dummy subpixel DSP can be located inside it.

Meanwhile, for convenience of explanation, the subpixels SP disposed in the second display region AA2 can be referred to as second subpixels SP2.

In this embodiment, when implementing the second display region AA2 in a delta arrangement (e.g., a delta or triangle configuration), for portions of the second display region AA2 located above and below the first display region AA1, the second subpixel SP2 located on the same column line as the first subpixel SP1 of the first display region AA1 can be configured to display the same color as the first subpixel SP1 of the first display region AA1. In other words, the first and second subpixels SP1 and SP2 arranged in each column line crossing the first and second display regions AA1 and AA2 can be configured to display the same color.

In this regard, for example, when the first subpixel SP1 of the first display region AA1 is the blue (B) subpixel SPb that displays blue, the second subpixel SP2 of the second display region AA2 located on the same column line can be the blue (B) subpixel SPb that displays blue. In addition, when the first subpixel SP1 of the first display region AA1 is the red (R) subpixel SPr that displays red, the second subpixel SP2 of the second display region AA2 located on the same column line can be the red (R) subpixel SPr that displays red. In addition, when the first subpixel SP1 of the first display region AA1 is the green (G) subpixel SPg that displays green, the second subpixel SP2 of the second display region AA2 located on the same column line can be the green (G) subpixel SPg that displays green.

As such, when the subpixels SP of the same color are arranged along each column line in the first and second display regions AA1 and AA2, color shift due to lateral leakage current in the vertical direction can be reduced or prevented. In this regard, for the first display region AA1 and the second display region AA2 located above and below the first display region AA1, the first subpixel SP1 and the second subpixel SP2 arranged in each column line emit the same color, so that even if lateral leakage current occurs in the vertical direction between the first and second display regions AA1 and AA2, color shift is not substantially caused.

Accordingly, in this embodiment, along a boundary in the horizontal direction between the first display region AA1 and the second display region AA2 (i.e., along a boundary between the first display region AA1 and the second display region AA2 above and below the first display region AA1), there is no need to form a lateral leakage current blocking structure such as a trench. Alternatively, a trench can be formed at the boundary in the horizontal direction between the first display region AA1 and the second display region AA2 to block a lateral leakage current in the vertical direction.

As above, in this embodiment, the subpixels SP can form the low-resolution second display region AA2 configured in a delta arrangement at the outer portion of the display region AA. Accordingly, color characteristics of the image can be improved.

In this regard, in a case in which the entire display region AA is configured in a stripe arrangement, asymmetry in horizontal and vertical color viewing angles and asymmetry in left and right color viewing angles can occur due to the characteristics of the stripe arrangement.

On the other hand, the delta arrangement can improve asymmetry in color viewing angle due to its characteristics. Accordingly, in this embodiment, by applying the delta arrangement at the outer portion of the display region AA, the asymmetry in color viewing angle can be alleviated to a significant extent, thereby improving imbalance in viewing angle.

Meanwhile, in this embodiment, color filter patterns CF corresponding to the subpixels SP of the display region AA can be disposed on a light output surface side, for example, over the light emitting diode OD.

Here, in the first display region AA1, the color filter patterns CF (or first color filter patterns CF1) can be formed in a stripe manner corresponding to the respective subpixels SP. Also, in the second display region AA2, the color filter patterns CF (or second color filter patterns CF2) can be formed in a delta manner corresponding to the respective subpixels SP.

In this regard, referring to FIGS. 1 to 4, in the first display region AA1, corresponding to the column line of each of the red (R), green (G), and blue (B) subpixels SPr, SPg, and SPb, each of red (R), green (G), and blue (B) color filter patterns CFr, CFg, and CFb can be provided in a form of continuously extending stripe.

In this regard, the red (R) color filter pattern CFr can be formed to continuously extend along the column line where the red (R) subpixels SPr are continuously arranged. In addition, the green (G) color filter pattern CFg can be formed to continuously extend along the column line where the green (G) subpixels (SPg) are continuously arranged. In addition, the blue (B) color filter pattern CFb can be formed to continuously extend along the column line where the blue (B) subpixels (SPb) are continuously arranged.

Meanwhile, in the second display region AA2, corresponding to each of the red (R), green (G), and blue (B) subpixels SPr, SPg, and SPb arranged in a delta shape, red (R), each of green (G), and blue (B) color filter patterns CFr, CFg, and CFb can be formed.

In this regard, each of the red (R), green (G), and blue (B) color filter patterns CFr, CFg, and CFb can extend to both sides in the horizontal direction (i.e., left and right), and can partially overlap the dummy subpixel DSP located in an adjacent column line. As an example, each of the red (R), green (G), and blue (B) color filter patterns CFr, CFg, and CFb can extend to both sides in the horizontal direction (i.e., left and right) by a length equal to or smaller than half of width of each subpixel, without being limited thereto. As an example, each of the red (R), green (G), and blue (B) color filter patterns CFr, CFg, and CFb can overlap half or less than half of the dummy subpixel DSP located in an adjacent column line, without being limited thereto.

In this regard, for example, the red (R) color filter pattern CFr corresponding to the red (R) subpixel SPr can extend to overlap the dummy subpixel DSP located in the left column line thereof and also extend to overlap the dummy subpixel DSP located in the right column line thereof. In addition, the green (G) color filter pattern CFg corresponding to the green (G) subpixel SPg can extend to overlap the dummy subpixel DSP located in the left column line thereof and also extend to overlap the dummy subpixel DSP located in the right column line thereof. In addition, the blue (B) color filter pattern CFb corresponding to the blue (B) subpixel SPb can extend to overlap the dummy subpixel DSP located in the left column line thereof and also extend to overlap the dummy subpixel DSP located in the right column line thereof.

In other words, for a column line where the subpixels SPr of the same color, for example, red (R), are arranged, in the dummy subpixel DSP placed in this column line, color filter patterns CFg and CFb of two different colors, for example, green (G) and blue (B), located on both sides of this column line can extend and be positioned. Here, the two different color filter patterns CF having portions extending into the dummy subpixel DSP can have substantially the same overlapping area with the dummy subpixel DSP (or can have substantially the same area located within the dummy subpixel DSP), but not limited thereto. As an example, one of the two different color filter patterns CF having portions extending into the dummy subpixel DSP can have a greater overlapping area with the dummy subpixel DSP than that of the other of the two different color filter patterns CF, without being limited thereto.

As such, when the color filter patterns CF of different colors are configured to extend into the dummy subpixel DSP, an unintended (or abnormal) emission phenomenon in the dummy subpixel DSP caused by a lateral leakage current in the vertical direction can be reduced or prevented.

In this regard, a case in which a lateral leakage current flows along a light emitting layer 145 from the blue (B) subpixel SPb located at an upper boundary of the first display region AA1 to the dummy subpixel DSP located at its upper side is given as an example. In this case, the red (R) and green (G) color filter patterns CFr and CFg on both sides of the dummy subpixel DSP can be extended and positioned in the dummy subpixel DSP. Accordingly, even if the lateral leakage current flows vertically from the blue (B) subpixel SPb to the dummy subpixel DSP, the dummy subpixel DSP is covered with the red (R) and green (G) color filter patterns CFr and CFg, output of blue light through the dummy subpixel DSP can be substantially prevented.

Therefore, in this embodiment, it is possible to prevent unintended emission in the second display region AA2 due to the vertical lateral leakage current from the first display region AA1 to the second display region AA2. Therefore, deterioration of color characteristics due to the lateral leakage current can be prevented.

Meanwhile, in this embodiment, as shown in FIG. 3, a trench (or first trench or a vertical trench) TC1 that extends in the vertical direction along a boundary of each column line (or a boundary between two neighboring column lines) of the display region AA can be formed.

In other words, the trenches TC1 can be formed along not only the boundaries of the column lines passing through both the first and second display regions AA1 and AA2 but also the boundaries of the column lines passing through the second display region AA2 located to the left and right of the first display region AA1.

As such, by forming the trench TC1 along the boundary of each column line in the display region AA, a lateral leakage current can be reduced or prevented from flowing along the horizontal direction between neighboring column lines where subpixels SP of different colors are positioned.

Accordingly, it is possible to reduce or prevent color shift from occurring in adjacent subpixels SP of different colors due to a lateral leakage current in the horizontal direction.

Hereinafter, a cross-sectional structure of the light emitting display device 10 of this embodiment is described in more detail with reference to FIGS. 5 to 7 along with FIGS. 1 to 4. FIG. 5 schematically shows a cross-sectional structure of the subpixels SP arranged along the horizontal direction in the first display region AA1, FIG. 6 schematically shows a cross-sectional structure of the subpixels SP and the dummy subpixels DSP arranged along the horizontal direction in the second display region AA2, and FIG. 7 schematically shows a cross-sectional structure of the subpixels SP and the dummy subpixels DP arranged along the vertical direction in the second display region AA2.

The substrate 101 of the light emitting display device 10 can use, for example, an insulating substrate such as a glass substrate or a plastic substrate. As another example, the substrate 101 can use a silicon substrate (or silicon wafer) formed of single crystalline silicon that functions as a semiconductor, and in this case, there is an advantage of effectively implementing a small display device that requires high resolution.

In this embodiment, for convenience of explanation, a case where an insulating substrate is used is taken as an example.

A plurality of thin film transistors TR can be formed in each subpixel SP on the substrate 101. Meanwhile, in this embodiment, for convenience of explanation, FIG. 5 shows one thin film transistor TR connected to the light emitting diode OD in the red (R) subpixel SPr. Meanwhile, the thin film transistor TR can be a light emission control thin film transistor or a driving thin film transistor, but not limited thereto.

Meanwhile, the thin film transistor TR can include a semiconductor layer, a gate insulating layer, a gate electrode, a source electrode, and a drain electrode. As the thin film transistor TR, a thin film transistor with a so-called bottom gate structure in which the gate electrode is located below the semiconductor layer, or a thin film transistor with a so-called top gate structure in which the gate electrode is located on the semiconductor layer can be used.

Meanwhile, when a semiconductor substrate is used as the substrate 101, an active region functioning as a semiconductor layer can be formed inside the semiconductor substrate.

At least one insulating layer can be formed on the thin film transistor TR. In this embodiment, for convenience of explanation, a case in which three insulating layers, first to third insulating layers 111 to 113, are formed is taken as an example.

The first insulating layer 111 can be formed substantially over the entire surface of the substrate 101 while covering the thin film transistor TR. The first insulating layer 111 can be formed of an organic insulating material or an inorganic insulating material.

On the first insulating layer 111, a first reflective plate 121 can be formed in the red (R) subpixel SPr of the display region AA (i.e., the first and second display regions AA1 and AA2).

A second insulating layer 112 can be formed substantially over the entire surface of the substrate 101 and on the first insulating layer 111 on which the first reflective plate 121 is formed. The second insulating layer 112 can be formed of an organic insulating material or an inorganic insulating material.

On the second insulating layer 112, a second reflective plate 122 can be formed in the green (G) subpixel SPg of the display region AA (i.e., the first and second display regions AA1 and AA2).

A third insulating layer 113 can be formed substantially over the entire surface of the substrate 101 and on the second insulating layer 112 on which the second reflective plate 122 is formed. The third insulating layer 113 can be formed of an organic insulating material or an inorganic insulating material.

On the third insulating layer 113, a third reflective plate 123 can be formed in the blue (B) subpixel SPb of the display region AA (i.e., the first and second display regions AA1 and AA2).

Each of the first to third reflective plates 121 to 123 can be formed of a metal with reflective property, for example, Ag, Al, Mo, Ti, or APC (Al—Pd—Cu) alloy, but not limited thereto. As an example, the first to third reflective plates 121 to 123 can be formed of the same material. As an example, at least one of the first to third reflective plates 121 to 123 can be formed of a different material from that of the other of the first to third reflective plates 121 to 123. As an example, the first to third reflective plates 121 to 123 can be formed on the same layer (e.g., the first insulating layer 111, or the third insulating layer 113), or can be formed on different layers. As an example, at least one of the first to third reflective plates 121 to 123 can be omitted depending on the design.

Meanwhile, a contact hole CH exposing one electrode of the thin film transistor TR, for example, a drain electrode can be formed in the first to third insulating layers 111 to 113.

The first to third reflectors 121 to 123 can each function to reflect a light, which is generated from the light emitting diode OD located thereon and travels downward in its subpixel SP, in an upward direction.

On the substrate 101 on which the third reflective plate 123 is formed, a first electrode (or anode) 140 of the light emitting diode OD can be formed for each subpixel SP. The first electrode 140 can be formed in a patterned form for each subpixel SP.

The first electrode 140 can be formed of a transparent conductive material such as ITO, IZO, ITZO, etc.

The first electrodes 140 formed in the red (R) subpixel SPr and the green (G) subpixel SPg can be formed on the third insulating layer 113. In addition, the first electrode 140 formed in the blue (B) subpixel SPb can be formed on the third reflective plate 123 of the blue (B) subpixel SPb.

As another example, an insulating layer can be formed on the third reflective plate 123 and substantially over the entire surface of the substrate 101, and the first electrode 140 can be formed for each subpixel SP on this insulating layer.

The first electrode 140 formed in each subpixel SP can be connected to the drain electrode of the thin film transistor TR of the corresponding subpixel SP through the contact hole CH.

Meanwhile, the reflective plates 121, 122, and 123 and the first electrode 140 may not be formed in the dummy subpixel DSP that is a non-emission region in the second display region AA2. As such, since the reflective plates 121, 122, 123 and the first electrode 140 are not formed in the dummy subpixel DSP, the dummy subpixel DSP is not equipped with a light emitting element and can substantially function as the non-emission region. Accordingly, emission action of the dummy subpixel DSP is reduced or prevented, thereby reducing or preventing deterioration of color characteristics in this region.

A bank (or partition) 143 surrounding the subpixel SP can be formed on the first electrode 140 along an edge of each subpixel SP. The bank 143 can be formed of an inorganic insulating material or an organic insulating material.

The bank 143 can be configured to have an opening that exposes the first electrode 140 of each subpixel SP and to cover an edge of the first electrode 140. Through the opening of the bank 143, an emission region (or the light emitting diode OD) in which light is substantially generated within the subpixel SP can be defined.

Meanwhile, the bank 143 can be formed to surround each dummy subpixel DSP along an edge of each dummy subpixel DSP, similar to the subpixel SP. In addition, the bank 143 can have an opening that exposes the third insulating layer 113 in a center region of each dummy subpixel DSP.

In the light emitting display device 10 of this embodiment, the trench TC1 can be formed in the bank 143. As mentioned above, the trench TC1 can be formed to extend along the vertical boundary between the neighboring column lines within the display region AA.

Accordingly, in the first display region AA1, the subpixels SP arranged in the neighboring column lines can be physically divided.

In addition, in the second display region AA2, the subpixel SP and the dummy subpixel DSP arranged in the neighboring column lines can be physically divided.

Meanwhile, the trench TC1 can extend inside the insulating layer located below the bank 143. For example, the trench TC1 can be formed in at least one insulating layer including the third insulating layer 113 among the first to third insulating layers 111 to 113. In this embodiment, the case where the trench TC1 is formed in the first to third insulating layers 111 to 113 is taken as an example. But embodiments are not limited thereto. As an example, the trench TC1 can penetrate all of the first to third insulating layers 111 to 113. As an example, the trench TC1 can penetrate into the substrate 101. As an example, the trench TC1 can penetrate into the third insulating layer 113 without penetrating the second insulating layer 112 and the third insulating layer 113.

The light emitting layer 145 can be formed on the bank 143 and on the first electrode 140 exposed through the opening of the bank 143. The light emitting layer 145 can be formed substantially over the entire surface of the substrate 101 (or the entire display region AA).

The light emitting layer 145 can be, for example, an organic light emitting layer formed using an organic material. In addition, the light emitting layer 145 can be formed in a single-layered structure or a multi-layered structure including an emitting material layer that actually emits light.

The light emitting layer 145 (or at least a portion of the light emitting layer 145) can be separated (or disconnected or divided) into each column line by the trench TC1 formed along the boundary of each column line, and can have a pattern form corresponding to each column line (or can have a stripe pattern form).

Here, the light emitting layer 145 can have a single-stack structure or a multi-stack structure. When the light emitting layer 145 has a single-stack structure, it can be completely separated into each column line by the trench TC1. When the light emitting layer 145 has a multi-stack structure, for example, a two-stack structure including a first stack as a lower stack, a second stack as an upper stack, and a charge generation layer between the first and second stacks, the first stack and the charge generation layer between the first and second stacks can be completely separated by the trench TC1, and at least a lower portion of the second stack can be separated. Embodiments are not limited thereto. As an example, all of the first stack, the charge generation layer, and the second stack can be completely separated by the trench TC1, without being limited thereto.

To form the light emitting layer 145 as described above, a material for the light emitting layer 145 can be deposited substantially over the entire display region AA of the substrate 101 through a deposition process. In this case, the material for the light emitting layer 145 may not be deposited on the trench TC1 but can be deposited in a form covering an inner surface of the trench TC1.

Accordingly, the material for the light emitting layer 145 can have a disconnected form at the trench TC1, so that the light emitting layer 145 can be separated with the trench TC1 as a boundary and be formed in a pattern in each column line, and the light emitting layer 145 can be formed to continuously extend along entirety of each column line. The material for the light emitting layer 145 can remain in a form of sediment on a bottom of the trench TC1.

The light emitting layer 145 can be formed of, for example, a white light emitting layer that emits white light. Accordingly, the light emitting diodes OD of all subpixels (SP) can emit the same white light.

As above, in this embodiment, forming the trench TC1 along the boundary of the column line, the light emitting layers 145 can be physically separated from each other between the neighboring column lines. Accordingly, a lateral leakage current in the horizontal direction through the light emitting layer 145 between the neighboring column lines heat lines can be reduced or prevented.

A second electrode (or cathode) 150 can be formed on the light emitting layer 145 substantially over the entire surface of the substrate 101.

In this regard, although the trench TC1 exists at the boundary between the column lines, a separation distance between the light emitting layers 145 at the trench TC1 can be substantially narrower than a width of the trench TC1. Accordingly, the second electrode 150 can be formed continuously without being disconnected over the trench TC1, and as a result, the second electrode 150 can be formed continuously along all subpixels SP in the display region AA.

The second electrode 150 can be formed of a metal having transflective property, for example, Mg, Ag, or an alloy of Mg and Ag (Mg: Ag).

As such, the reflective plate 121, 122 or 123 and the second electrode 150 are located at a lower portion and an upper portion in each subpixel SP with the light emitting layer 145 therebetween, so that a micro cavity structure can be implemented.

In this regard, the red (R) subpixel SPr, the green (G) subpixel SPg, and the blue (B) subpixel SPb output light of different colors, that is, different wavelengths, and thus can have different cavity thicknesses (or resonance distances) (i.e., different distances between the respective reflective plates and the second electrode).

In this regard, the subpixels SPr, SPg, and SPb that display red (R), green (G), and blue (B) have cavity thicknesses proportional to the corresponding color wavelengths (or half wavelengths), and the cavity thickness of each subpixel SP can be matched to an integer multiple of the half wavelength of the corresponding color.

In this regard, the subpixel SPr of red (R) which is the longest wavelength can have a corresponding first cavity thickness by placing the first reflective plate 121 closest to the substrate. The subpixel SPg of green (G) which is the middle wavelength can have a corresponding second cavity thickness by placing the second reflective plate 122 at a higher position than the first reflective plate 121. The subpixel SPb of blue (B) which is the shortest wavelength can have a corresponding third cavity thickness by placing the third reflective plate 123 at the highest position.

As such, by using the micro cavity structure, color purity and light efficiency can be improved.

Moreover, for the subpixels SP of different colors, the corresponding micro cavity thicknesses can be realized by differentiating the positions of the corresponding reflective plates 121, 122, and 123. Thus, the light emitting diodes OD of the subpixels SP can have substantially the same thickness, so that the light emitting diodes OD can have substantially the same characteristics.

On the second electrode 150, an encapsulation layer 160 that encapsulates the substrate 101 on which the second electrode 150 is formed can be formed over the entire surface of the substrate 101. The encapsulation layer 160 can block penetration of moisture or oxygen from the outside and improve reliability.

Moreover, the encapsulation layer 160 can planarize the substrate 101 on which the second electrode 150 is formed.

The encapsulation layer 160 can be formed in a single-layered structure or a multi-layered structure using at least one of an inorganic insulating material and an organic insulating material.

On the encapsulation layer 160, the color filter pattern CF can be provided to correspond to each subpixel SP and implement the corresponding color.

In this regard, the color filter pattern CF can include the red (R), green (G), and blue (B) color filter patterns CFr, CFg, and CFb that correspond to the red (R), green (G), and blue (B) subpixels SPr, SPg, and SPb to generate red (R), green (G), and blue (B), respectively.

Accordingly, the red (R), green (G), and blue (B) subpixels SPr, SPg, and SPb can display the corresponding colors with higher purity.

Meanwhile, as mentioned above, in the second display region AA2, the color filter patterns CF of different colors located on both sides of the dummy subpixel DSP in the horizontal direction can extend inside the dummy subpixel DSP. In other words, in the second display region AA2, the color filter pattern CF of the subpixel SP of each column line can extend inside the dummy subpixels DSP on both sides in the horizontal direction.

An overcoat layer 170 can be formed on the color filter pattern CF to cover and protect the color filter pattern CF. The substrate 101 on which the overcoat film 170 is formed can have a substantially flat surface.

On the overcoat film 170, a lens Lc corresponding to each subpixel SP of the display region AA can be formed. The lens Lc can have an upwardly convex shape.

The lens Lc can be substantially aligned correctly with the light emitting diode OD (or emission region) of the corresponding subpixel SP. For example, a center of the lens Lc can be aligned to substantially coincide with a center of the light emitting diode OD of the subpixel SP.

The lens Lc can function to collect a light due to its convex shape, thereby improving a front luminance of the light emitting display device 10.

Meanwhile, the lens Lc may not be formed in the dummy subpixel DSP which is a non-emission region in the second display region AA2.

A planarization film 180 for planarizing the substrate can be formed on the lens Lc and the overcoat film 170.

The planarization film 180 can have a smaller refractive index than the lens Lc therebelow. In this regard, for example, the lens Lc can have a refractive index of about 1.6 to 1.8, and the planarization film 180 can have a refractive index of about 1.4 to 1.5. Embodiments are not limited thereto. As an example, as long as the planarization film 180 can have a smaller refractive index than the lens Lc therebelow, the lens Lc and the planarization film 180 can have any refractive index (e.g., a refractive index lower than 1.6 or 1.4 or a refractive index higher than 1.8 or 1.5).

### Second Embodiment

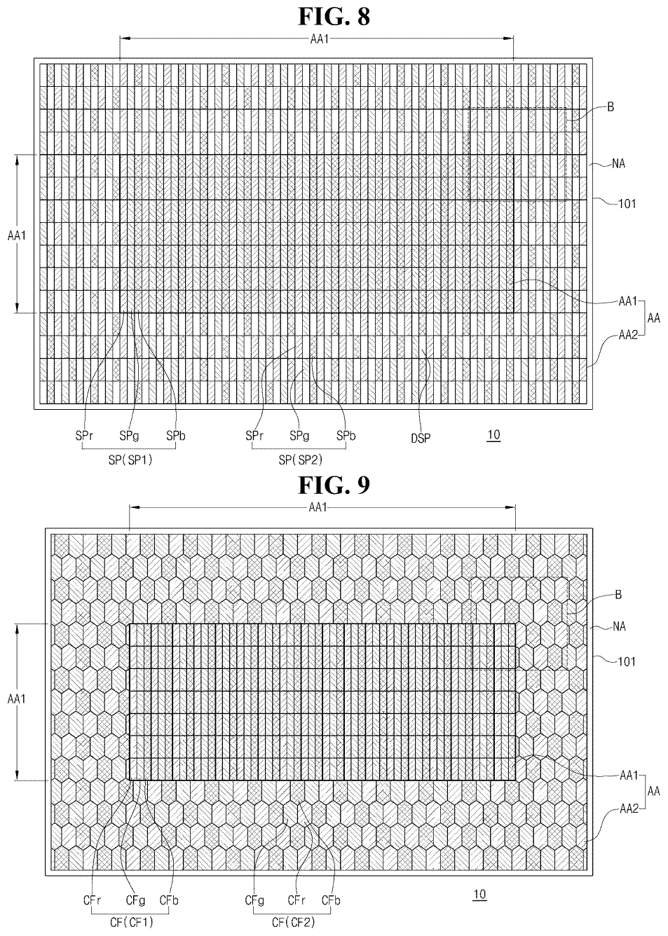

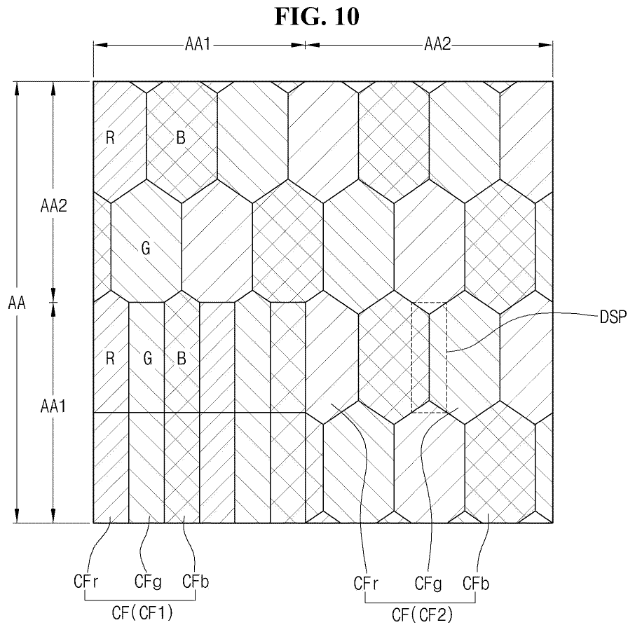

FIGS. 8 and 9 are plan views schematically illustrating an arrangement of subpixels and an arrangement of color filter patterns of a light emitting display device according to a second embodiment of the present invention, respectively. FIG. 10 is a view enlarging a region B of FIG. 9.

In the following description, detailed descriptions of configurations identical to or similar to those of the above-described first embodiment can be omitted or may be briefly provided.

Referring to FIGS. 8 to 10, in the light emitting display device 10 of this embodiment, the arrangement of the subpixels SP in the first display region AA1 and the second display region AA2 can be similar to that of the first embodiment.

In this regard, the first subpixels SP1 which are the subpixels SP in the high-resolution first display region AA1 can be configured in a stripe type arrangement. In addition, the second subpixels SP2 which are the subpixels SP in the low-resolution second display region AA2 can be configured in a delta type arrangement.

In addition, the arrangement of the color filter patterns CF in the first display region AA1 and the second display region AA2 can be similar to that of the first embodiment.

In this regard, the first color filter patterns CF1 which are the color filter patterns CF in the high-resolution first display region AA1 can be configured in a stripe type arrangement. In addition, the second color filter patterns CF2 which are the color filter patterns CF in the low-resolution second display region AA2 can be configured in a delta type arrangement.

Meanwhile, in this embodiment, similar to the first embodiment, the color filter pattern CF in the second display region AA2 can extend in the horizontal direction and overlap the dummy subpixel DSP of an adjacent column line. In addition, the color filter pattern CF in the second display region AA2 can extend in the vertical direction and overlap the dummy subpixel DSP of an adjacent row line.

In other words, for each dummy subpixel DSP, the color filter patterns CF of the subpixels SP adjacent to the dummy subpixel DSP in the horizontal direction can extend and overlap the dummy subpixel DSP, and the color filter patterns CF of the subpixels SP adjacent to the dummy subpixel DSP in the vertical direction can extend and overlap the dummy subpixel DSP.

As such, in this embodiment, in the second display region AA2, the color filter pattern CF can be formed to extend from the corresponding subpixel SP to the dummy subpixel DSP in the horizontal direction and the dummy subpixel DSP in the vertical direction.

Accordingly, in the second display region AA2, the color filter pattern CF can have, for example, a substantially hexagonal shape in plan view. Embodiments are not limited thereto. As an example, the color filter pattern CF extended from the corresponding subpixel SP to the dummy subpixel DSP in the horizontal direction and the color filter pattern CF extended from the corresponding subpixel SP to the dummy subpixel DSP in the vertical direction can be in contact with each other, without being limited thereto. As an example, the boundaries between color filter patterns CF inside one dummy subpixel DSP can extend along various direction (e.g., inclined directions other than the horizontal direction or the vertical direction), to intersect with each other, without being limited thereto.

In this regard, taking the blue (B) color filter pattern CFb as an example, the blue (B) color filter pattern CFb can have a portion extending in a substantially trapezoidal shape to each of the dummy subpixels (DSP) located on both sides (i.e., left and right) of the horizontal direction, and can have a portion extending in a substantially triangular shape to each of the dummy subpixels (DSP) located on both sides (i.e., upper and lower sides) of the vertical direction. Accordingly, the blue (B) color filter pattern CFb can be formed in a substantially hexagonal shape.

Similarly, each of the red (R) color filter pattern CFr and the green (G) color filter pattern CFg can also extend in the horizontal and vertical directions to be formed in a substantially hexagonal shape.

As such, the color filter pattern CF can be formed to extend in the horizontal and vertical directions in the second display region AA2, so that color characteristics can become more uniform.

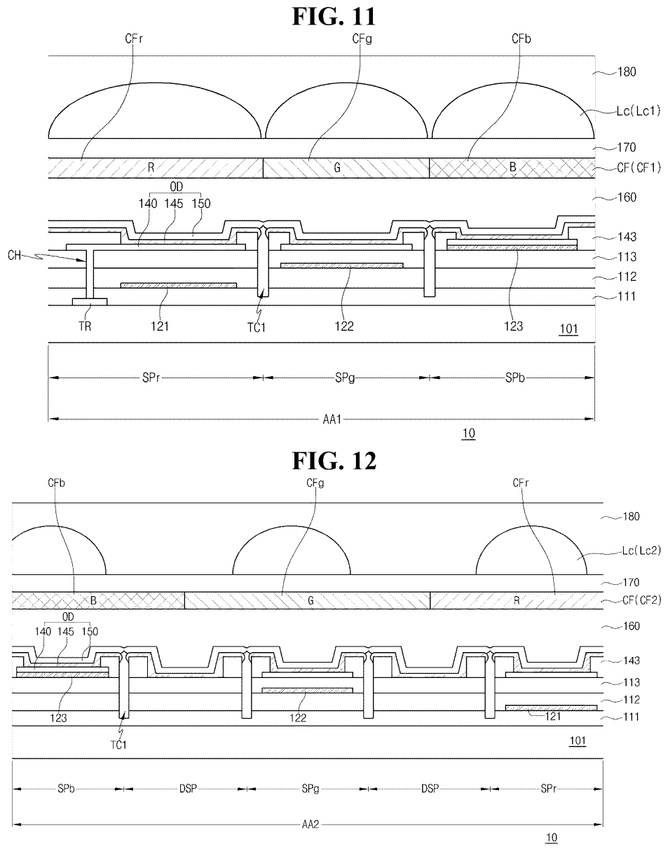

Meanwhile, in this embodiment, similar to the first embodiment, the trench (TC1 in FIGS. 11 and 12) can be formed in the vertical direction along the boundary of each column line of the display region AA. Accordingly, it is possible to block a lateral leakage current from flowing along the horizontal direction between the adjacent column lines where the subpixels SP of different colors are arranged.

In addition, in this embodiment, in the second display region AA2, a second lens (Lc2 in FIGS. 11 and 12) which is a lens Lc disposed on the second color filter pattern CF2 can be configured to be shifted to a certain distance in a direction toward the first display region AA1. Accordingly, light generated in the second display region AA2, which is the low-resolution region located in the outer portion of the display region AA, can be changed in path and collected to the center region which is the user's main visual field, so that luminance of the outer portion of the display region AA can be improved. Embodiments are not limited thereto. As an example, a center of the second lens (Lc2 in FIGS. 11 and 12) can be configured to be aligned with center of the light emitting diode OD of the corresponding subpixel SP, without being limited thereto.

The lens shift structure of the second display region AA2 is described with reference to FIGS. 11 and 12.

FIG. 11 is a cross-sectional view schematically illustrating a cross-sectional structure of subpixels arranged along a horizontal direction in a first display region of a light emitting display device according to a second embodiment of the present invention, and FIG. 12 is a cross-sectional view schematically illustrating a cross-sectional structure of subpixels arranged along a horizontal direction in a second display region of a light-emitting display device according to a second embodiment of the present invention.

Referring to FIG. 11, similar to the first embodiment, in the first display region AA1, the first lens Lc1, which is the lens Lc disposed corresponding to the first subpixel SP1, can be substantially aligned correctly with the light emitting diode OD of the first subpixel SP1. For example, a center of the first lens Lc1 can be aligned to substantially coincide with a center of the light emitting diode OD of the first subpixel SP1.

Meanwhile, referring to FIG. 12, unlike the first embodiment, in the second display region AA2, the second lens Lc2, which is the lens Lc disposed corresponding to the second subpixel SP2, can be substantially misaligned with the light emitting diode OD of the second subpixel SP2. For example, a center of the second lens Lc2 can be shifted in the direction toward the first display region AA1 and can be located not to coincide with a center of the light emitting diode OD of the second subpixel SP2. As an example, at least apportion of the second lens Lc2 can still overlap at least a portion of the light emitting diode OD of the second subpixel SP2.

Here, the second display region AA2 in FIG. 12 is located on the right side of the first display region AA1, so that the second lens Lc2 can be shifted to the left toward the first display region AA1. Based on this, the second lens Lc2 in the second display region AA2 which is located on the left side of the first display region AA1 can be shifted to the right, the second lens Lc2 in the second display region AA2 which is located on the upper side of the first display region AA1 can be shifted in the downward direction, and the second lens Lc2 in the second display region AA2 which is located on the lower side of the first display region AA1 can be shifted in the upward direction. Embodiments are not limited thereto. As an example, at least one of the second lens Lc2 in the second display region AA2 which is located on the right side, the left side, the upper side and the lower side of the first display region AA1 can be shifted in the direction toward the first display region AA1. As an example, at least one of the second lens Lc2 in the second display region AA2 which is located on the right side, the left side, the upper side and the lower side of the first display region AA1 may not be shifted in the direction toward the first display region AA1.

As such, in this embodiment, the second lens Lc2 can be shifted toward the first display region AA1, so that the second lens Lc2 can partially overlap the dummy subpixel DSP adjacent to the second lens Lc2 in the direction toward the first display region AA1. Embodiments are not limited thereto. As an example, the second lens Lc2 may not overlap the dummy subpixel DSP adjacent to the second lens Lc2 in the direction toward the first display region AA1, although being shifted toward the first display region AA1.

Meanwhile, the second lens Lc2 of this embodiment can be applied to the first embodiment described above. That is, in the light emitting display device 10 of the first embodiment, the lens Lc disposed in the second display region AA2 can be formed to be shifted in the direction toward the first display region AA1.

### Third Embodiment

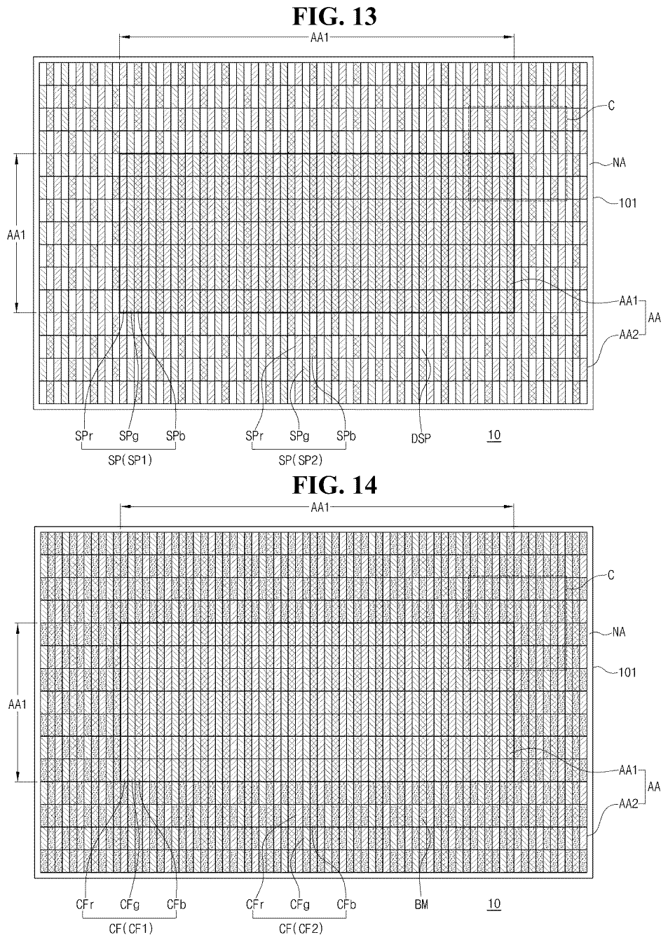

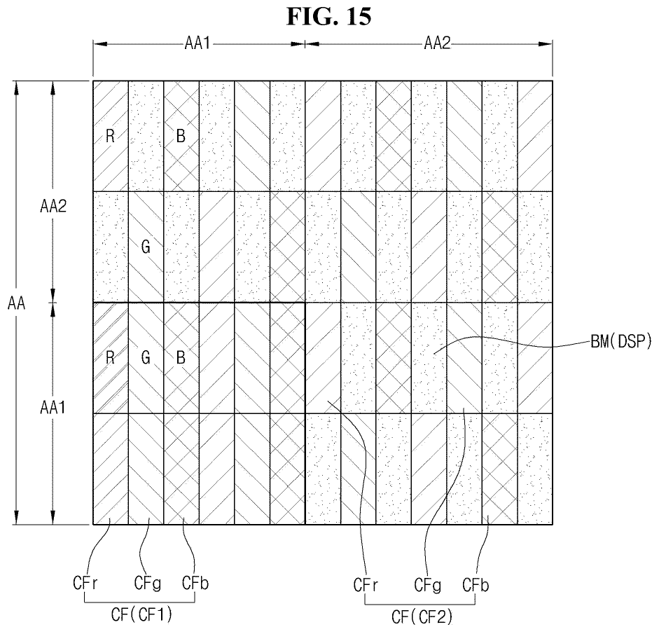

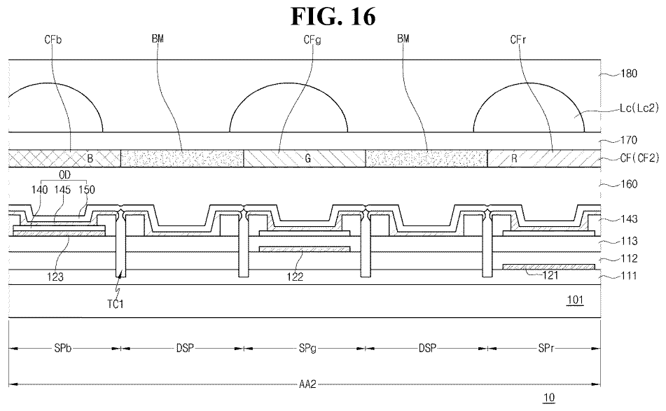

FIG. 13 is a plan view schematically illustrating an arrangement of subpixels of a light emitting display device according to a third embodiment of the present invention, and FIG. 14 is a plan view schematically illustrating an arrangement of color filter patterns and black matrices of a light emitting display device according to the third embodiment of the present invention. FIG. 15 is a view enlarging a region C of FIG. 14. FIG. 16 is a cross-sectional view schematically illustrating a cross-sectional structure of subpixels arranged along a horizontal direction in a second display region of a light emitting display device according to the third embodiment of the present invention.

In the following description, detailed descriptions of configurations identical to or similar to those of the first and second embodiments described above can be omitted or may be briefly provided.

Referring to FIGS. 13 to 16, in the light emitting display device 10 of this embodiment, the arrangement of the subpixels SP in the first display region AA1 and the second display region AA2 can be similar to that of the first embodiment.

In this regard, the first subpixels SP1 which are the subpixels SP in the high-resolution first display region AA1 can be configured in a stripe type arrangement. In addition, the second subpixels SP2 which are the subpixels SP in the low-resolution second display region AA2 can be configured in a delta array structure.

In addition, the arrangement structure of the color filter patterns CF in the first display region AA1 and the second display region AA2 can be similar to that of the first embodiment.

In this regard, the first color filter patterns CF1 which are the color filter patterns CF in the high-resolution first display region AA1 can be configured in a stripe type arrangement. In addition, the second color filter patterns CF2 which are the color filter patterns CF in the low-resolution second display region AA2 can be configured in a delta type arrangement.

Meanwhile, in this embodiment, black matrices BM can be formed corresponding to the respective dummy subpixels DSP in the second display region AA2. As an example, the black matrix BM can be formed on the encapsulation layer 160, without being limited thereto. As an example, the black matrix BM can be formed on the same layer as or a different layer from the color filter patterns. As an example, an edge of the black matrix BM can be in contact with an edge of the color filter patterns. As an example, a boundary between the black matrix BM and the color filter patterns can be located between adjacent subpixel and the dummy subpixels DSP, or can be located inside the dummy subpixels DSP, without being limited thereto. The black matrix BM can be formed corresponding to the dummy subpixel DSP, so that the black matrix BM can be formed in an island pattern shape.

As such, as the black matrix BM is formed in the dummy subpixel DSP of the second display region AA2, the second color filter pattern CF2 which is the color filter pattern CF of the second display region AA2 can be formed to have a size (or area) substantially corresponding to the second subpixel SP2.

In other words, unlike the first and second embodiments, the second color filter pattern CF2 may not extend to the dummy subpixel DSP adjacent to it in the horizontal direction and may not extend to the dummy subpixel DSP adjacent to it in the vertical direction. That is, the second color filter pattern CF2 can be formed to non-overlap the dummy subpixels DSP adjacent to it in the horizontal and vertical directions.

As described above, when the black matrix BM is formed in the dummy subpixel DSP of the second display region AA2, light output from the dummy subpixel DSP can be prevented.

Accordingly, even if a lateral leakage current in the vertical direction flows into the dummy subpixel DSP, unintended emission due to this can be reduced or prevented, and thus color characteristic deterioration due to the lateral leakage current in the vertical direction can be reduced or prevented.

Meanwhile, in this embodiment, similar to the first and second embodiments, the trench TC1 can be formed in the vertical direction along the boundary of each column line of the display region AA. Accordingly, it is possible to block a lateral leakage current from flowing along the horizontal direction between the adjacent column lines where the subpixels SP of different colors are arranged.

In addition, in this embodiment, similar to the second embodiment, in the second display region AA2, the second lens Lc2 which is the lens Lc disposed on the second color filter pattern CF2 can be configured to be shifted to a certain distance in a direction toward the first display region AA1. Accordingly, light generated in the second display region AA2, which is the low-resolution region located in the outer portion of the display region AA, can be changed in path and collected to the center region which is the user's main visual field, so that luminance of the outer portion of the display region AA can be improved.

### Fourth Embodiment

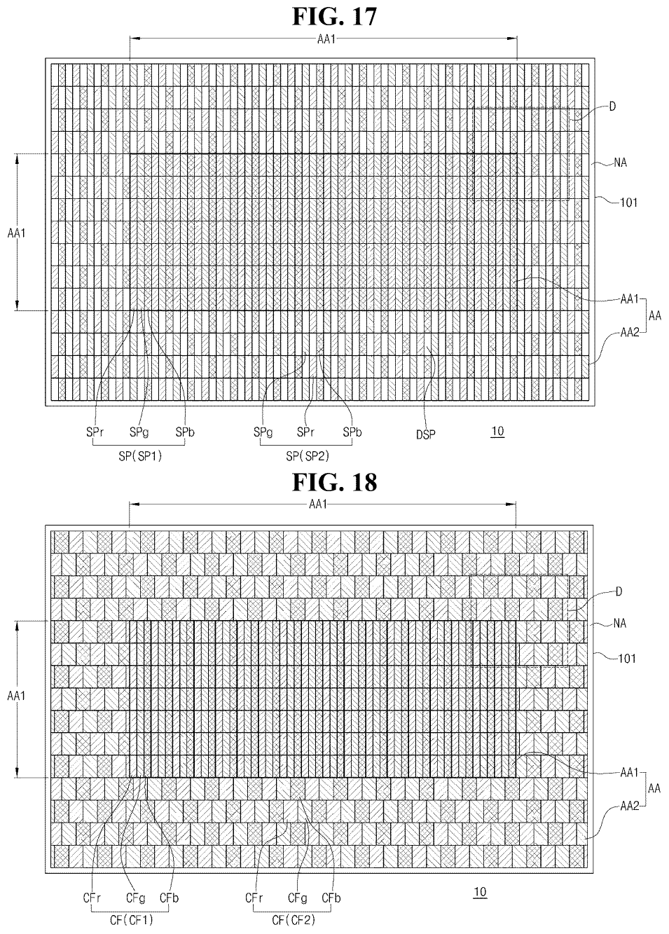

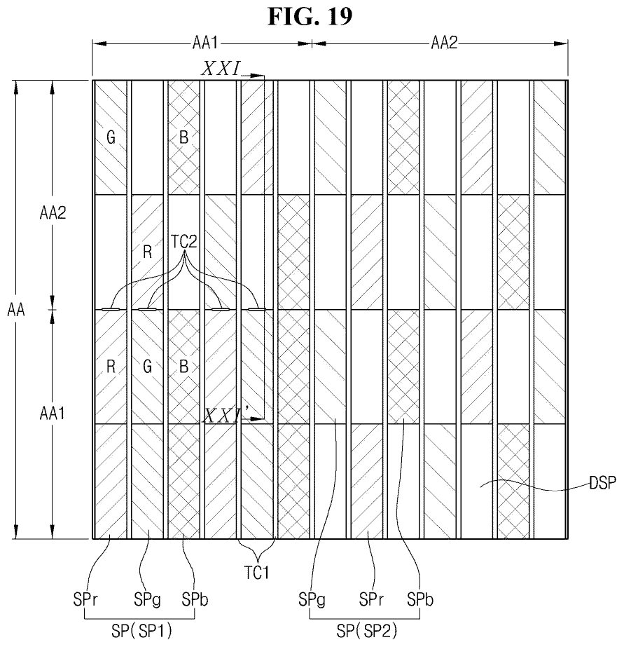

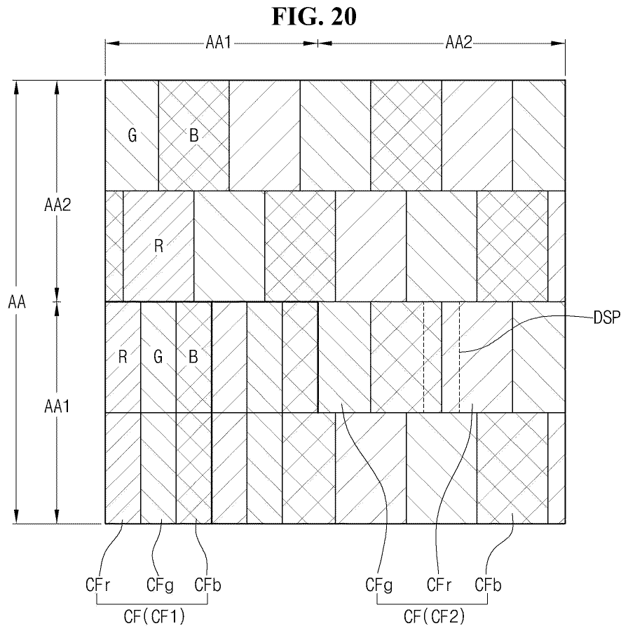

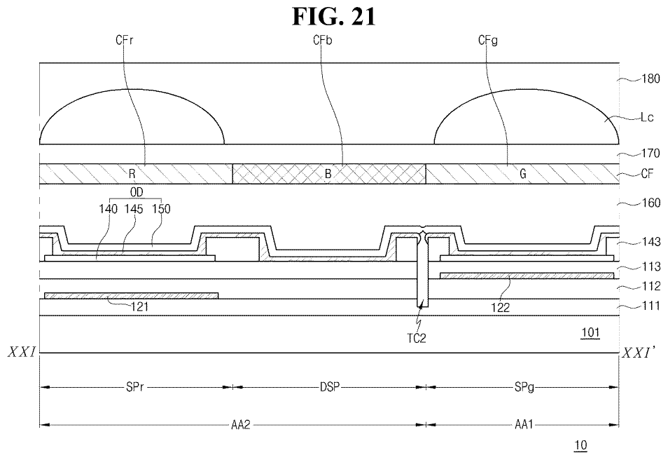

FIGS. 17 and 18 are plan views schematically illustrating an arrangement of subpixels and an arrangement of color filter patterns of a light emitting display device according to a fourth embodiment of the present invention, respectively. FIGS. 19 and 20 are views enlarging regions D of FIGS. 17 and 18, respectively. FIG. 21 is a cross-sectional view taken along a line XXI-XXI′ of FIG. 19.

In the following description, detailed descriptions of configurations identical to or similar to those of the first to third embodiments described above can be omitted.

Referring to FIGS. 17 to 21, in the light emitting display device 10 of this embodiment, the arrangement of the subpixels SP in the first display region AA1 and the second display region AA2 can be similar to that of the first embodiment.

In this regard, the first subpixels SP1 which are the subpixels SP in the high-resolution first display region AA1 can be configured in a stripe type arrangement. In addition, the second subpixels SP2 which are the subpixels SP in the low-resolution second display region AA2 can be configured in a delta type arrangement.

In addition, the arrangement of the color filter patterns CF in the first display region AA1 and the second display region AA2 can be similar to that of the first embodiment.

In this regard, the first color filter patterns CF1 which are the color filter patterns CF in the high-resolution first display region AA1 can be configured in a stripe type arrangement. In addition, the second color filter patterns CF2 which are the color filter patterns CF in the low-resolution second display region AA2 can be configured in a delta type arrangement.

Meanwhile, in this embodiment, the arrangement relationship between the red (R), green (G), and blue (B) subpixels SPr, SPg, and SPb of the second subpixels SP2 in the second display region AA2 can be different from that of the first embodiment. Accordingly, the arrangement relationship of the red (R), green (G), and blue (B) color filter patterns CFr, CFg, and CFb of the second color filter patterns CF2 can be different from that of the first embodiment.

For example, regarding the red (R), green (G), and blue (B) subpixels SPr, SPg, and SPb arranged in the first to third column lines, which are three neighboring column lines, on one column line out of the three column lines, the first and second subpixels SP1 and SP2 of the same color can be arranged in the first and second display regions AA1 and AA2, and on each of the remaining two column lines out of the three column lines, the first and second subpixels SP1 and SP2 of different colors can be arranged in the first and second display regions AA1 and AA2.

In this embodiment, for convenience of explanation, a case where along the third column line, the blue (B) subpixels SPb are arranged identically in both the first and second display regions AA1 and AA2; along the first column line, the red (R) subpixels SPr are arranged in the first display region AA1 and the green (G) subpixels SPg are arranged in the second display region AA2; and along the second column line, the green (G) subpixels SPg are arranged in the first display region AA1 and the red (R) subpixels SPr are arranged in the second display region AA2 is taken as an example.

Regarding this arrangement relationship, the blue (B) subpixel SPb can cause the greatest color shift due to its lateral leakage current. Thus, in order to reduce or minimize the color shift, the blue (B) subpixel SPb can be positioned on the same column line of the first and second display regions AA1 and AA2.

Alternatively, the red (R) subpixel SPr or green (G) subpixel SPg can be configured to be arranged in the same column line of the first and second display regions AA1 and AA2.

To correspond to the arrangement relationship of the red (R), green (G), and blue (B) subpixels SPr, SPg, and SPb in the first and second display regions (AA1, AA2) as above, the arrangement relationship of the red (R), green (G), and blue (B) color filter patterns CFr, CFg, and CFb in the first and second display regions AA1 and AA2 can be set.

In this regard, along the third column line, the blue (B) color filter patterns CFb can be arranged in both the first and second display regions AA1 and AA2; along the first column line, the red (R) color filter patterns CFr can arranged in the first display region AA1 and the green (G) color filter patterns CFg can be arranged in the second display region AA2; and along the second column line, the green (G) color filter pattern CFg can be arranged in the first display region AA1 and the red (R) color filter pattern CFr can be arranged in the second display region AA2.

Similar to the first embodiment, the color filter pattern CF in the second display region AA2 can extend in the horizontal direction and overlap the dummy subpixels DSP located in its adjacent column lines.

In this regard, for example, the red (R) color filter pattern CFr corresponding to the red (R) subpixel SPr can extend to overlap the dummy subpixel DSP located to the left thereof and also extend to overlap the dummy subpixel DSP located the right thereof. In addition, the green (G) color filter pattern CFg corresponding to the green (G) subpixel SPg can extend to overlap the dummy subpixel DSP located to the left thereof and also extend to overlap the dummy subpixel DSP located to the right thereof. In addition, the blue (B) color filter pattern CFb corresponding to the blue (B) subpixel SPb can extend to overlap the dummy subpixel DSP located to the left thereof and also extend to overlap the dummy subpixel DSP located to the right thereof.

Meanwhile, in this embodiment, similar to the first embodiment, a first trench TC1, which is a trench extending in the vertical direction along the boundary of each column line of the display region AA, can be formed.

Moreover, in this embodiment, a second trench TC2, which is a trench extending in the horizontal direction along the horizontal boundaries between the first display region AA1 and the second display region AA2 (i.e., the horizontal boundary between the first display region AA1 and the second display region AA2 located above the first display region AA1, and the horizontal boundary between the first display region AA1 and the second display region AA2 located below the first display region AA1), can be formed.

Here, the second trench TC2 can be formed in the column lines where the subpixels SP of different colors are arranged in the first and second display regions AA1 and AA2, for example, in the first and second column lines where the red (R) and green (G) subpixels SPr and SPg are arranged in the first and second display regions AA1 and AA2. In this regard, the second trench TC2 can be formed between the first subpixel SP1 closest to the boundary of the first display region AA1, and the second subpixel SP2 or dummy subpixel DSP closest to the boundary of the second display region AA2.

In addition, the second trench TC2 may not be formed in the column line where the subpixels SP of the same color are arranged in the first and second display regions AA1 and AA2, for example, in the third column line where the blue (B) subpixels SPb are arranged in the first and second display regions AA1 and AA2. As another example, the second trench TC2 can be formed in the third column line where the blue (B) subpixels SPb are arranged.

As above, in the column line where the subpixel SP of the first display region AA1 and the subpixel SP of the second display region AA2 are different in color, the horizontal second trench TC2 can be formed at the horizontal boundary between the first and second display regions AA1 and AA2, so that a lateral leakage current in the vertical direction between the first and second display regions AA1 and AA2 can be blocked. Accordingly, it is possible to reduce or prevent color shift from occurring due to the lateral leakage current in the vertical direction in the column line where the subpixels SP of different colors are arranged.

Meanwhile, in the column line where the subpixels SP of the first and second display regions AA1 and AA2 are identical in color, the horizontal second trench TC2 may not be formed at the boundary between the first and second display regions AA1 and AA2. In this regard, as previously mentioned in the first embodiment, a lateral leakage current that emits the same color flows in the vertical direction in the column line of the same color, so that in the subpixels SP located in this column line, color shift is not substantially caused. In addition, in the dummy subpixels DSP arranged in the column line of the same color, the color filter patterns CF of colors different from the color of this column line can be arranged, so that unintentional emission from the dummy subpixel DSP due to a lateral leakage current can be reduced or prevented, thereby reducing or preventing deterioration of color characteristics.

The second trench TC2 can be formed to, for example, be spaced apart from the first trench TC1 extending in the vertical direction without crossing (or meeting) the first trench TC1. In other words, ends of the second trench TC2 can be formed to be spaced apart from the first trenches TC1 extending along the boundaries of the corresponding column line. That is, the second trenches TC2 formed in two adjacent column lines can be formed to be spaced apart from each other with the first trench TC1 along the boundary between the two column lines being located therebetween.

In this regard, if the second trench TC2 is formed to cross and meet the first trench TC1, a trench width at and near the crossing portion of the first and second trenches TC1 and TC2 can increase, and in this case, a problem can occur in which the second electrode 150 of the light emitting diode OD is cut off unintentionally.

Therefore, in this embodiment, the second trench TC2 can be formed to be spaced apart from the first trench TC1 without crossing the first trench TC1, thereby reducing or preventing occurrence of defects in the light emitting diode OD.

Meanwhile, the second trench TC2 can be formed in the same process as the first trench TC1. For example, the second trench TC2 can be formed in the bank 143 and can extend into the insulating layer below the bank 143 or the substrate 101. Embodiments are not limited thereto. As an example, the second trench TC2 and the first trench TC1 can be formed in separate processes. As an example, the second trench TC2 can have the same thickness and/or the same width as the first trench TC1, or can have a different thickness and/or a different width from the first trench TC1.

In the light emitting display device 10 of this embodiment, the lens Lc disposed in the second display region AA2 can be correctly aligned with the corresponding light emitting diode OD. As another example, similar to the second embodiment described above, the lens Lc disposed in the second display region AA2 can be formed to be shifted in the direction toward the first display region AA1.

### Fifth Embodiment

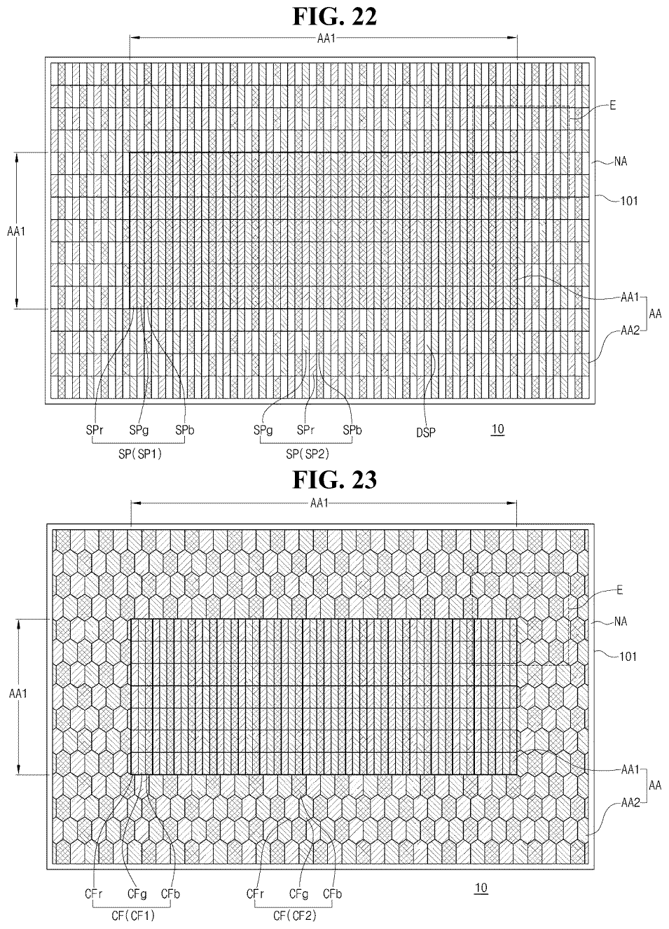

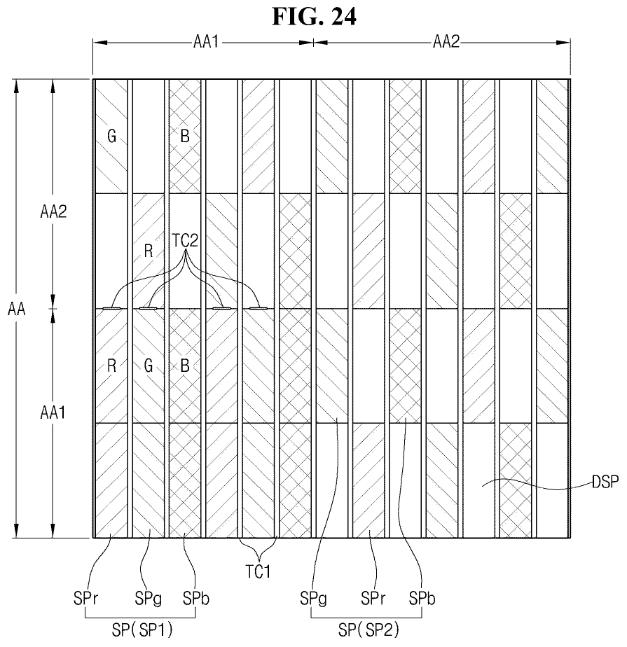

FIGS. 22 and 23 are plan views schematically illustrating an arrangement of subpixels and an arrangement of color filter patterns of a light emitting display device according to a fifth embodiment of the present invention, respectively. FIG. 24 is a view enlarging a region E of FIG. 22.

In the following description, detailed descriptions of configurations identical to or similar to those of the first to fourth embodiments described above can be omitted or may be briefly provided.

Referring to FIGS. 22 to 24, in the light emitting display device 10 of this embodiment, the arrangement of the subpixels SP in the first display region AA1 and the second display region AA2 can be similar to that of the fourth embodiment.

In this regard, the first subpixels SP1 which are the subpixels SP in the high-resolution first display region AA1 can be configured in a stripe type arrangement. In addition, the second subpixels SP2 which are the subpixels SP in the low-resolution second display region AA2 can be configured in a delta type arrangement.

In addition, the arrangement of the color filter patterns CF in the first display region AA1 and the second display region AA2 can be similar to that of the fourth embodiment.

In this regard, the first color filter patterns CF1 which are the color filter patterns CF in the high-resolution first display region AA1 can be configured in a stripe type arrangement. In addition, the second color filter patterns CF2 which are the color filter patterns CF in the low-resolution second display region AA2 can be configured in a delta type arrangement.

Meanwhile, in this embodiment, similar to the second embodiment, the color filter pattern CF in the second display region AA2 can extend in the horizontal direction and overlap the dummy subpixel DSP of an adjacent column line. In addition, the color filter pattern CF in the second display region AA2 can extend in the vertical direction and overlap the dummy subpixel DSP of an adjacent row line.

In other words, for each dummy subpixel DSP, the color filter patterns CF of the subpixels SP adjacent to the dummy subpixel DSP in the horizontal direction can extend and overlap the dummy subpixel DSP, and the color filter patterns CF of the subpixels SP adjacent to the dummy subpixel DSP in the vertical direction can extend and overlap the dummy subpixel DSP.

As such, in this embodiment, in the second display region AA2, the color filter pattern CF can be formed to extend from the corresponding subpixel SP to the dummy subpixel DSP in the horizontal direction and the dummy subpixel DSP in the vertical direction.

Accordingly, in the second display region AA2, the color filter pattern CF can have, for example, a substantially hexagonal shape in plan view.

As such, the color filter pattern CF can be formed to extend in the horizontal and vertical directions in the second display region AA2, so that color characteristics can become more uniform.

Meanwhile, in this embodiment, similar to the fourth embodiment, the first trench TC1 can be formed in the vertical direction along the boundary of each column line of the display region AA.

In addition, similar to the fourth embodiment, the second trench TC2 can be formed at the horizontal boundary between the first display region AA1 and the second display region AA2.

Accordingly, it is possible to block a lateral leakage current of different color from flowing along the vertical and horizontal directions, thereby reducing or preventing color shift in adjacent subpixel SP.

In this embodiment, similar to the second embodiment, in the second display region AA2, a second lens (Lc2 in FIGS. 11 and 12) which is a lens disposed on the second color filter pattern CF2 can be configured to be shifted to a certain distance in a direction toward the first display region AA1. Accordingly, light generated in the second display region AA2, which is the low-resolution region located in the outer portion of the display region AA, can be changed in path and collected to the center region which is the user's main visual field, so that luminance of the outer portion of the display region AA can be improved.

### Sixth Embodiment

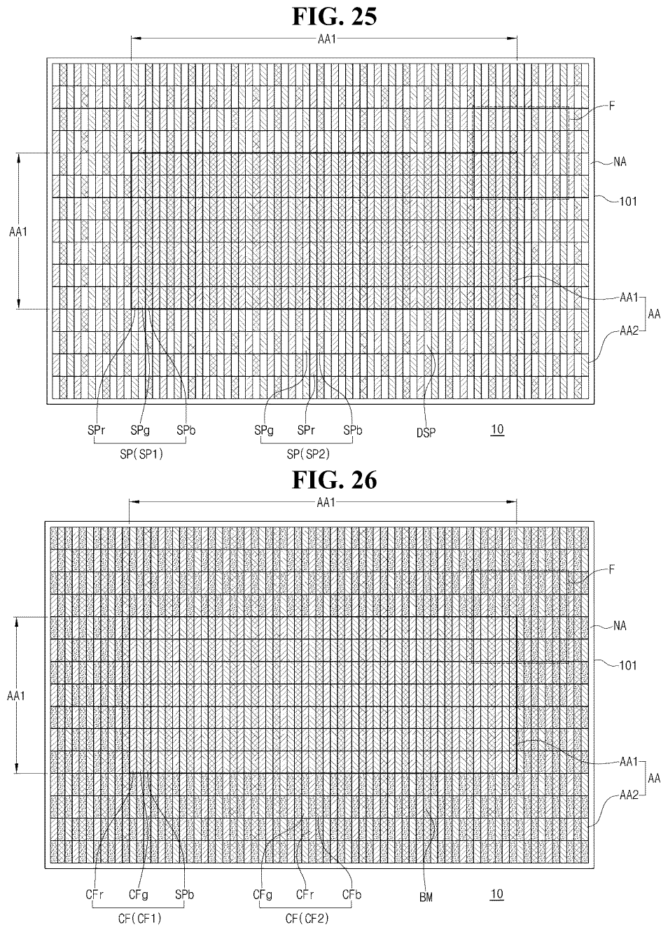

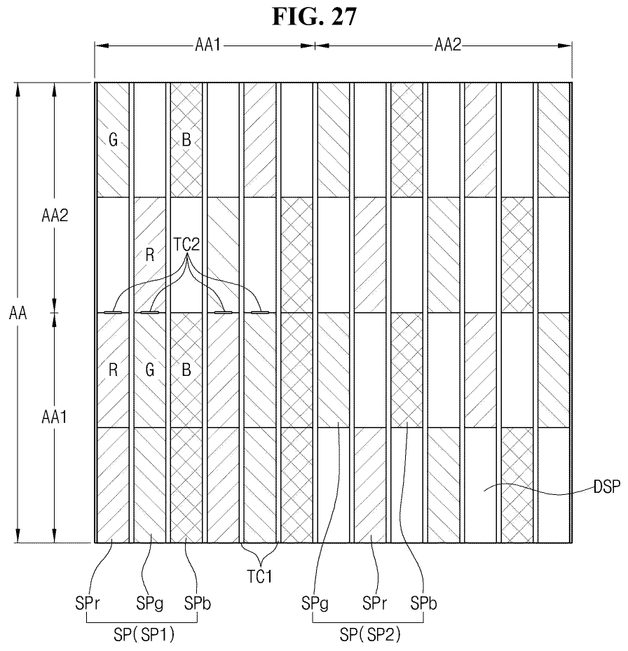

FIG. 25 is a plan view schematically illustrating an arrangement of subpixels of a light emitting display device according to a sixth embodiment of the present invention, and FIG. 26 is a plan view schematically illustrating an arrangement of color filter patterns and black matrices of a light emitting display device according to the sixth embodiment of the present invention. FIG. 27 is a view enlarging a region F of FIG. 25.

In the following description, detailed descriptions of configurations identical to or similar to those of the first to fifth embodiments described above can be omitted or may be briefly provided.

Referring to FIGS. 25 to 27, in the light emitting display device 10 of this embodiment, the arrangement of the subpixels SP in the first display region AA1 and the second display region AA2 can be similar to that of the fourth or fifth embodiment.

In this regard, the first subpixels SP1 which are the subpixels SP in the high-resolution first display region AA1 can be configured in a stripe type arrangement. In addition, the second subpixels SP2 which are the subpixels SP in the low-resolution second display region AA2 can be configured in a delta type arrangement.

In addition, the arrangement of the color filter patterns CF in the first display region AA1 and the second display region AA2 can be similar to that of the fourth embodiment.

In this regard, the first color filter patterns CF1 which are the color filter patterns CF in the high-resolution first display region AA1 can be configured in a stripe type arrangement. In addition, the second color filter patterns CF2 which are the color filter patterns CF in the low-resolution second display region AA2 can be configured in a delta type arrangement.

Meanwhile, in this embodiment, similar to the third embodiment, the black matrices BM can be formed corresponding to the respective dummy subpixels DSP in the second display region AA2. The black matrix BM can be formed corresponding to the dummy subpixel DSP, so that the black matrix BM can be formed in an island pattern shape.

As such, as the black matrix BM is formed in the dummy subpixel DSP of the second display region AA2, the second color filter pattern CF2 which is the color filter pattern CF of the second display region AA2 can be formed to have a size substantially corresponding to the second subpixel SP2.

In other words, the second color filter pattern CF2 may not extend to the dummy subpixel DSP adjacent to it in the horizontal direction and may not extend to the dummy subpixel DSP adjacent to it in the vertical direction. That is, the second color filter pattern CF2 can be formed to non-overlap the dummy subpixels DSP adjacent to it in the horizontal and vertical directions.

As described above, when the black matrix BM is formed in the dummy subpixel DSP of the second display region AA2, light output from the dummy subpixel DSP can be reduced or prevented.

Accordingly, even if a lateral leakage current in the vertical direction flows into the dummy subpixel DSP, unintended emission due to this can be reduced or prevented, and thus color characteristic deterioration due to the lateral leakage current in the vertical direction can be reduced or prevented.

Meanwhile, in this embodiment, similar to the fourth or fifth embodiment, the first trench TC1 can be formed in the vertical direction along the boundary of each column line of the display region AA.

In addition, similar to the fourth or fifth embodiment, the second trench TC2 can be formed at the horizontal boundary between the first display region AA1 and the second display region AA2.

Accordingly, it is possible to block a lateral leakage current of different color from flowing along the vertical and horizontal directions, thereby reducing or preventing color shift in adjacent subpixel SP.

In this embodiment, similar to the third embodiment, in the second display region AA2, a second lens (Lc2 in FIG. 16) which is a lens Lc disposed on the second color filter pattern CF2 can be configured to be shifted to a certain distance in a direction toward the first display region AA1. Accordingly, light generated in the second display region AA2, which is the low-resolution region located in the outer portion of the display region AA, can be changed in path and collected to the center region which is the user's main visual field, so that luminance of the outer portion of the display region AA can be improved.

As described above, according to the embodiments of the present invention, the high-resolution first display region can be formed at the center portion of the display region with the subpixels arranged in a stripe manner, and the low-resolution second display region can be formed at the outer portion of the display region with the subpixels arranged in a delta manner.

By applying the delta type arrangement to the outer portion of the display region, the asymmetry in color viewing angle can be alleviated, thereby improving imbalance in viewing angle. In addition, as the outer portion of the display region has a low resolution, the user can view a natural image, thereby improving sense of immersion in the image.

The vertical trench can be formed along the boundary of each column line in the display region, or in addition, the horizontal trench can be formed along the horizontal boundary between the first and second display regions. Accordingly, it is possible to block a lateral leakage current from flowing in the vertical direction or in the vertical and horizontal directions, thereby reducing or preventing color shift from occurring in adjacent subpixel of different color.

In the second display region, the color filter pattern can be formed to extend to adjacent dummy subpixels in the horizontal direction or in the horizontal and vertical directions. Accordingly, the color characteristics of the light emitting display device can become more uniform.

The lens located in the second display region can be configured to be shifted in the direction toward the first display region. Accordingly, the light in the second display region can be collected to the user's main visual field, thereby improving the luminance of the outer portion of the display region.

The black matrix can be formed in the dummy subpixel of the second display region. Accordingly, even if a lateral leakage current flows into the dummy subpixel, light output can be reduced or prevented, thereby reducing or preventing deterioration of color characteristics due to the dummy subpixel.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A light emitting display device, comprising:
a substrate on which a display region is defined, the display region including a first display region and a second display region located outside the first display region, the first display region having subpixels of first to third colors arranged in a stripe manner, and the second display region having subpixels of the first to third colors arranged in a delta manner;
a first electrode formed in each of first subpixels disposed in the first display region and formed in each of second subpixels disposed in the second display region;
a bank including a first trench formed along a boundary of each column line of the display region and covering an edge of the first electrode;
a light emitting layer formed on the first electrode and the bank;
a second electrode formed on the light emitting layer; and
a color filter pattern located on the second electrode and corresponding to each of the first and second subpixels,
wherein in the second display region, a dummy subpixel is arranged alternately with the second subpixel along column lines and row lines and has a size corresponding to the second subpixel, and
wherein the first and second subpixels arranged in a first column line crossing the first and second display regions display the first color.

2. The light emitting display device of claim 1, wherein the first and second subpixels disposed in a second column line adjacent to one side of the first column line display the second color, and
wherein the first and second subpixels arranged in a third column line adjacent to another side of the first column line display the third color.

3. The light emitting display device of claim 1, wherein the first and second subpixels disposed in a second column line adjacent to one side of the first column line display the second and third colors, respectively, and
wherein the first and second subpixels disposed in a third column line adjacent to another side of the first column line display the third and second colors, respectively.

4. The light emitting display device of claim 3, wherein in each of the second and third column lines, a second trench is formed in the bank along a boundary in a row direction between the first and second display regions, and
wherein the second trench is spaced apart from the first trench adjacent thereto.

5. The light emitting display device of claim 1, wherein the dummy subpixel overlaps the color filter pattern corresponding to the subpixel of a column line adjacent to the dummy subpixel in a row direction.

6. The light emitting display device of claim 5, wherein the dummy subpixel overlaps the color filter pattern corresponding to the subpixel of a row line adjacent to the dummy subpixel in a column direction.

7. The light emitting display device of claim 6, wherein the color filter pattern corresponding to the second subpixel has a hexagonal shape.

8. The light emitting display device of claim 1, wherein the dummy subpixel is provided with a black matrix located on the second electrode.

9. The light emitting display device of claim 5, wherein the first and second subpixels are provided with first and second lenses located on the color filter patterns, respectively,
wherein a center of the first lens coincides with a center of an emission region of the first subpixel, and
wherein a center of the second lens is shifted from a center of an emission region of the second subpixel toward the first display region.

10. The light emitting display device of claim 9, wherein the second lens overlaps the dummy subpixel adjacent thereto in a direction toward the first display region.

11. The light emitting display device of claim 8, wherein the first and second subpixels are provided with first and second lenses located on the color filter patterns, respectively,
wherein a center of the first lens coincides with a center of an emission region of the first subpixel, and
wherein a center of the second lens is shifted from a center of an emission region of the second subpixel toward the first display region.

12. The light emitting display device of claim 11, wherein the second lens overlaps the dummy subpixel adjacent thereto in a direction toward the first display region.

13. The light emitting display device of claim 1, further comprising:
a thin film transistor located in one of the subpixels; and
at least one insulating layer located between the thin film transistor and the first electrode and including a contact hole through which the first electrode and the thin film transistor are connected.

14. The light emitting display device of claim 13, wherein the first trench extends inside the at least one insulating layer.

15. The light emitting display device of claim 1, wherein the light emitting layer emits white light.

16. The light emitting display device of claim 1, wherein the first to third colors are different colors selected from red, green, and blue.

17. A light emitting display device, comprising:
a substrate on which a display region is defined, the display region including a first display region and a second display region located outside the first display region, the first display region including subpixels of first to third colors arranged in a stripe manner, and the second display region including subpixels of the first to third colors arranged in a delta manner;
a light emitting diode provided in one subpixel among the subpixels, and including first and second electrodes and a light emitting layer disposed between the first and second electrodes;
a first trench formed along a boundary of each column line of the display region and separating adjacent light emitting layers; and
a color filter pattern corresponding to the one subpixel and located on the light emitting diode,
wherein in the second display region, a dummy subpixel is arranged alternately with the one subpixel along column lines and row lines, and
wherein in a first column line crossing the first and second display regions, first subpixels arranged in the first display region and second subpixels arranged in the second display region display the first color.

18. The light emitting display device of claim 17, wherein the first and second subpixels disposed in a second column line adjacent to one side of the first column line display the second color, and
wherein the first and second subpixels arranged in a third column line adjacent to another side of the first column line display the third color.

19. The light emitting display device of claim 17, wherein the first and second subpixels disposed in a second column line adjacent to one side of the first column line display the second and third colors, respectively, and
wherein the first and second subpixels disposed in a third column line adjacent to another side of the first column line display the third and second colors, respectively.

20. The light emitting display device of claim 19, wherein in each of the second and third column lines, a second trench is formed along a boundary in a row direction between the first and second display regions, and
wherein the second trench is spaced apart from the first trench adjacent thereto.

21. The light emitting display device of claim 17, wherein the color filter pattern corresponding to the second subpixel extends into and overlaps the dummy subpixel of a column line adjacent to the color filter pattern in a row direction.

22. The light emitting display device of claim 21, wherein the color filter pattern corresponding to the second subpixel extends into and overlaps the dummy subpixel of a row line adjacent to the color filter pattern in a column direction.

23. The light emitting display device of claim 22, wherein the color filter pattern corresponding to the second subpixel has a hexagonal shape.

24. The light emitting display device of claim 17, wherein the dummy subpixel is provided with a black matrix located on the second electrode.

25. The light emitting display device of claim 21, wherein the first and second subpixels are provided with first and second lenses located on color filter patterns, respectively,
wherein a center of the first lens coincides with a center of an emission region of the first subpixel, and
wherein a center of the second lens is shifted from a center of an emission region of the second subpixel toward the first display region.

26. The light emitting display device of claim 25, wherein the second lens overlaps the dummy subpixel adjacent thereto in a direction toward the first display region.

27. The light emitting display device of claim 24, wherein the first and second subpixels are provided with first and second lenses located on color filter patterns, respectively,
wherein a center of the first lens coincides with a center of an emission region of the first subpixel, and
wherein a center of the second lens is shifted from a center of an emission region of the second subpixel toward the first display region.

28. The light emitting display device of claim 27, wherein the second lens overlaps the dummy subpixel adjacent thereto in a direction toward the first display region.

29. The light emitting display device of claim 17, wherein the light emitting layer emits white light.

30. The light emitting display device of claim 17, wherein the first to third colors are different colors selected from red, green, and blue.
